(19) United States
(12) Patent Application Publication
(10) Pub. No.: US 2012/0049330 A1
(43) Pub. Date: Mar. 1, 2012

(54) SILICON WAFER AND METHOD FOR PRODUCING THE SAME

(75) Inventor: Yasushi Yukimoto, Tokyo (JP)

(73) Assignee: SUMCO CORPORATION, Tokyo (JP)

(21) Appl. No.: 13/266,159

(22) PCT Filed: Apr. 9, 2010
(86) PCT No.: PCT/JP2010/002613

§ 371 Date: Oct. 25, 2011

(30) Foreign Application Priority Data
May 15, 2009 (JP) 2009-118674

(51) Int. Cl. H01L 29/36; H01L 21/322; H01L 21/20

(52) U.S. Cl. 257/617; 438/479; 438/473; 257/E21.318; 257/E21.09; 257/E29.109

(57) ABSTRACT

A method of producing a silicon wafer comprises the steps of subjecting a silicon wafer, which has been sliced from a silicon single crystal ingot grown by the Czochralski method, to RTA treatment in a nitriding gas atmosphere; forming an oxide film on a surface of either side of the wafer; then forming a polysilicon layer thereon. The polysilicon layer on the front side of the wafer is removed and a wafer free of crystal defects in the surface part and with improved gettering performance is obtained. The polysilicon layer may be formed not on the surface of either side of the wafer but only on the back side thereof. It is desirable that a wafer composed of only a defect-free region is used as the source material since a defect-free layer can be stably secured in the wafer surface part.

### TECHNICAL FIELD

The present invention relates to a silicon wafer having high gettering performance, which is suitably used for a semiconductor device substrate or the like, and a method for producing the silicon wafer.

### BACKGROUND ART

A silicon wafer to be used as a semiconductor device substrate is generally made such that a silicon single crystal ingot grown by the Czochralski method (hereinafter referred to as “CZ method”) is sliced and processed into a finished product through various steps such as polishing.

Such a silicon wafer contains oxygen as an impurity, and this oxygen impurity forms oxygen precipitates [hereinafter referred to as “BMD (Bulk Micro Defect)”], which causes the dislocation, defects or the like. It is known that the BMD is grown and formed from minute nuclei (oxygen precipitates nuclei) as being introduced into a silicon single crystal during pulling-up thereof, for example, by heat treatment such as oxidation heat treatment in a device fabrication process. When this BMD is present in the surface part of a wafer on which a semiconductor device is to be formed, it seriously affects characteristics of the device, that is, causes an increase in leak current, deterioration of the insulating property of an oxide film (gate oxide integrity) or the like.

On the other hand, BMD that is formed inside the wafer becomes a gettering site for capturing and removing contaminant impurities (particularly, metal impurities) from the surface part of the wafer. In the device fabrication process, for example, in dry etching step or the like, an apparatus that causes metal contamination is occasionally used and it is thus extremely important for the wafer to have excellent gettering performance.

Therefore, there have been conventionally developed methods for producing a silicon wafer which is free from defects such as oxygen precipitates in the surface part, and has a gettering site such as the oxygen precipitates, a polycrystal silicon (polysilicon) layer or a highly-diffused phosphorus layer, inside the wafer or on the back side thereof.

For example, in a method of producing a silicon wafer presented in Patent Literature 1, a wafer, after heat-treated in an atmosphere containing nitriding gas such as NH₃ to inject vacancies into the wafer, is subjected to high-temperature heat treatment to form a defect-free layer [hereinafter referred also to as “DZ layer” (Denuded Zone)] on the surface of the silicon, and then subjected to oxygen precipitation heat treatment to internally precipitate BMD. As the nitriding gas, instead of N₂ (nitrogen) which was mainly used in the past, a gas lower in decomposition temperature than N₂, such as NH₃, is used, whereby the nitriding gas can be decomposed at a low heat treatment temperature or in a short heat treatment time to internally inject the vacancies, and slip generation during the heat treatment can be also suppressed.

In a method of producing a silicon wafer described in Patent Literature 2, a wafer is subjected to extrinsic gettering by a poly-back-seal method, and then subjected to rapid heat-up/cool-down heat treatment, or RTA (Rapid Thermal Annealing) treatment (hereinafter referred to as “RTA treatment”) under reducing atmosphere by use of a rapid heating/rapid cooling device in order to reduce COP (Crystal Originated Particle) on the wafer surface. According to this, the COP can be surely extinguished without deterioration of gettering performance.

However, the method described in Patent Literature 1 has a problem in which the gettering performance is low until BMD is sufficiently precipitated by the oxygen precipitation heat treatment after injecting the vacancies into the wafer. Therefore, for example, the wafer can be contaminated (particularly, contaminated with metal) in a heat treatment furnace while being subjected to the oxygen precipitation heat treatment.

In the method described in Patent Literature 2, since the heat treatment is performed under reducing atmosphere, vacancies cannot be newly injected in the subsequent treatment, thus BMD as gettering sites cannot be created inside the wafer.

### CITATION LIST

### Patent Literature

### PATENT LITERATURE 1: Japanese Patent Application Publication No. 2003-31582

### PATENT LITERATURE 2: Japanese Patent Application Publication No. 2000-31153

### SUMMARY OF INVENTION

### Technical Problem

The present invention thus has an object to solve the above-mentioned problems and provide a silicon wafer which is free from crystal defects in the surface part and is further improved in gettering performance, and a method for producing the same.

### Solution to Problem

For eliminating adverse effects on a silicon wafer by contaminant impurities or the like during the device fabrication process, it is necessary to remove the contaminant impurities (particularly, metal impurities) from the device-forming region of the wafer. Therefore, adopted is a process to impart the gettering performance to the wafer itself while inhibiting the mixture of contaminants from the process as much as possible. The gettering process in this case includes an external gettering for forming the gettering sites for capturing the contaminant impurities on the back side of the wafer (Extrinsic Gettering) and an internal gettering for faulting the gettering sites inside the wafer, for example, on the lower side of the device-forming layer (Intrinsic Gettering).

In order to further improve the gettering performance of the silicon wafer, the present inventor has attempted to form the gettering sites also on the back side of the wafer while forming the gettering sites inside the wafer. Concretely, the silicon wafer is subjected to the RTA treatment in nitriding gas atmosphere, a polysilicon layer is thereafter formed on the back side of the wafer to form extrinsic gettering sites, and the resulting wafer is successively heat treated at a temperature lower than the treatment temperature in the RTA treatment to thereby precipitate BMD inside the wafer as intrinsic gettering sites.

As a result of investigations, the present inventor found that the polysilicon layer(s) can be formed on both surfaces or the reverse surface of wafer without forming a single crystal silicon layer, particularly, by adding a step of forming an oxide film(s) on the surface(s) of wafer which has been subjected to the RTA treatment, and confirmed that a silicon wafer subjected to extrinsic gettering and intrinsic gettering and having a defect-free layer in the surface part can be produced.

The present invention is summarized in a method of producing a silicon wafer according to (1) or (2) described below, and silicon wafers of (3)-(5) described below, which are produced by the method.

(1) A method of producing a silicon wafer, including the steps of: subjecting a silicon wafer, which has been sliced from a silicon single crystal ingot grown by the CZ method, to RTA treatment in nitriding gas atmosphere; forming an oxide film on a surface of either side of the wafer after the RTA treatment; forming a polysilicon layer on a surface of either side of wafer, the surface having the oxide film formed thereon; and removing the polysilicon layer on the wafer surface (or principal surface of wafer) (referred to as “a first production method”).

(2) A method of producing a silicon wafer, including the steps of: subjecting a silicon wafer, which has been sliced from a silicon single crystal ingot grown by the CZ method, to RTA treatment in nitriding gas atmosphere; forming an oxide film on the back side of the wafer after the RTA treatment; and forming a polysilicon layer on the back side of the wafer, the back side having the oxide film formed thereon (hereinafter referred to as “a second production method”).

In the first or second production method, it is desirable to use a wafer composed of a defect-free region as the silicon wafer to be subjected to the RTA treatment since a defect-free layer can be stably secured in the surface part of the wafer.

In the first or second production method, as the step of forming the oxide film, there can be adopted a step including an operation to heat the wafer in oxidizing atmosphere after treating the wafer surface with hydrofluoric acid, or a step including an operation to heat the wafer in oxidizing atmosphere after polishing the wafer surface.

It is desirable to adopt an embodiment in which a silicon wafer produced by the first or second production method is heat-treated at a temperature lower than that of the RTA treatment (such heat treatment is referred also to as “oxygen precipitation heat treatment”) to precipitate oxygen at vacancies inside the wafer while forming a defect-free layer on the wafer surface. According to this production method, it becomes possible to obtain a silicon wafer which is enhanced in gettering performance by extrinsic gettering and intrinsic gettering incorporation and has the defect-free layer formed in the wafer surface part.

(3) A silicon wafer having high gettering performance, which is produced by the first or second production method.

(4) A silicon wafer having high gettering performance, comprising: precipitate nuclei inside the wafer, the nuclei functioning to form an oxygen precipitate layer by heat treatment to be performed in a semiconductor device fabrication process; and a polysilicon layer on the back side of the wafer.

(5) A silicon wafer having high gettering performance, comprising: an oxygen precipitate layer inside the wafer; and a polysilicon layer on the back side of the wafer.

### Advantageous Effects of Invention

According to the method of the present invention for producing a silicon wafer, it is possible to produce a silicon wafer which has a defect-free layer in the surface part and is improved in gettering performance by incorporating extrinsic gettering and intrinsic gettering. By incorporating the extrinsic gettering, the gettering performance can be imparted to the wafer until BMD is sufficiently formed inside the wafer by the oxygen precipitation heat treatment or heat treatment to be performed in a device fabrication process. The extrinsic gettering is incorporated by the polysilicon layer formation on the back side of the wafer. The intrinsic gettering is incorporated by the polysilicon layer forming step and further the subsequent oxygen precipitation heat treatment or otherwise, by heat treatment in the device fabrication process to which the wafer is served as a material.

The silicon wafer according to the present invention is the one having high gettering performance, which is produced by the production method of the present invention and is improved in overall gettering performance by incorporating extrinsic gettering and intrinsic gettering, and this silicon wafer can be suitably used for a semiconductor device substrate or the like. By incorporating the extrinsic gettering, the gettering performance can be imparted to the wafer until BMD is sufficiently formed inside the wafer by the oxygen precipitation heat treatment or, otherwise, by heat treatment to be performed in the device fabrication process.

### BRIEF DESCRIPTION OF DRAWINGS

FIG. 1 is a view for showing a relationship between a ratio of V/G (V: pulling rate of silicon single crystal, G: temperature gradient along a growth direction within a single crystal just after pulled up) and concentrations of interstitial silicon type point defects and vacancy-type point defects.

FIG. 2 is a view for showing BMD density in a silicon wafer produced by the production method of the present invention in comparison to comparative examples.

### DESCRIPTION OF EMBODIMENTS

A first production method of the present invention includes the steps of: subjecting a silicon wafer, which has been sliced from a silicon single crystal ingot grown by the CZ method, to RTA treatment in a nitriding gas atmosphere; forming an oxide film on a surface of either side of the wafer after the RTA treatment; forming a polysilicon layer on a surface of either side of the wafer, the surface having the oxide film formed thereon; and removing the polysilicon layer only on the front side of the wafer among those formed on either side of the wafer. Each step will be then described in detail.

(a) Step of Subjecting Silicon Wafer to RTA Treatment in a Nitriding Gas Atmosphere

The wafer as a blank material for a silicon wafer of the present invention is sliced from a silicon single crystal ingot grown by the CZ method. This blank wafer is subjected to the RTA treatment to inject vacancies, extending from the surface part to the inside of the blank wafer, and then subjected to the after-mentioned oxygen precipitation heat treatment, whereby high-density BMD can be formed inside the wafer. Otherwise, without performing the oxygen precipitation heat treatment, the high-density BMD can be formed inside the wafer by subjecting the wafer to heat treatment to be applied after and in association with the device fabrication process that is carried out for the blank wafer of a semiconductor device substrate or the like, Therefore, not only a wafer entirely composed of a defect-free region to be described later but also a silicon wafer obtained from a single crystal ingot grown by the general CZ method, which contains crystal detects such as COP, can be used as the blank material.

The oxygen concentration in the wafer is desirably in the range of 7×10¹⁷ to 16×10¹⁷ atoms/cm³ (ASTM F-121, 1979). If the oxygen concentration is less than 7×10¹⁷ atoms/cm³, the formation itself of BMD precipitate nuclei is suppressed to thereby decrease the amount of BMD inside the wafer. Further, the problem of deterioration of the strength of the wafer is also caused.

The RTA treatment is performed in a nitriding gas atmosphere. By performing the RTA treatment in a nitriding gas atmosphere, vacancies can be injected into the wafer. Although the composition of the atmosphere gas is not particularly specified, preferred is a mixed gas of an inert gas with NH₃ (ammonia) or the like that is decomposed at a temperature lower than the case of N₂ to form a nitrided film on the wafer surface to allow the injection of vacancies into the wafer. For example, Ar gas or the like containing 0.5% NH₃, which was used in after-mentioned EXAMPLES, is preferred.

The temperature and time in the RTA treatment can be appropriately set, considering the density of the oxygen precipitate (BMD) layer to be internally formed by heat treatment to be performed later (oxygen precipitation treatment) or the like. Since an excessively low temperature in the treatment requires an extended treatment time, and an excessively high temperature causes silicon to melt, it is desired to perform heat treatment at a temperature range from 1150° C. to the melting point of silicon (1410° C.). The treatment time is desirably set to 60 seconds or less from the viewpoint of reducing slip generation, although it depends on the treatment temperature. In the heat-up stage of the RTA treatment, the heat-up rate is desirably set to 10 to 150° C./sec. The productivity is poor at a rate below 10° C./sec, and slip dislocation is apt to occur in the wafer at a rate exceeding 150° C./sec. The cool-down rate in the cool-down stage is also desirably set in the range of 10 to 150° C./sec from the same viewpoint as the heat-up rate.

A conventionally-used apparatus can be used for the RTA treatment. A lamp annealing furnace of a type to heat by a halogen lamp is desirably used since the heat-up/cool-down can be rapidly performed, and the treatment can be performed without giving excessive heat amount to the silicon wafer.

(b) Step of Forming an Oxide Film on a Surface of Either Side of Silicon Wafer After RTA Treatment

Oxide films are formed on both surfaces of the silicon wafer which has been subjected to the above-mentioned RTA treatment.

The method for forming the oxide films is not particularly limited. For example, after the surface thereof is treated with hydrofluoric acid, a method of heating the silicone wafer in an atmosphere containing oxygen (air) at 600 to 700° C. for about 10 minutes can be applied. The same heat treatment may be performed after the surface of the silicon wafer is polished.

(c) Step of Forming a Polysilicon Layer on a Surface of Either Side of Silicon Wafer

Polysilicon layers are formed on both the surfaces of the silicon wafer after the oxide film deposition. In this polysilicon layer forming step, precipitate nuclei of BMD can be grown to increase BMD in the vicinity of depth-wise central part of the wafer (near the center part, in the range of 350 to 450 μm from the wafer surface) and in the vicinity of surface thereof (inside the wafer, in the range of 50 to 150 μm from the wafer surface).

The polysilicon layer formation can be performed by a CVD method which is generally used. Namely, a source gas such as silane (SiH₄) is introduced into a reaction furnace to precipitate and grow Si on surfaces of wafer heated to 600 to 700° C. The layer thickness is desirably set to 0.1 to 10 μm. A layer thickness of 0.1 μm or more can provide sufficient gettering performance, while one of the polysilicon layers formed on either side surface of wafer is left in the subsequent step to function as gettering sites. On the other hand, when the layer thickness exceeds 10 the productivity is deteriorated.

(d) Step of Removing a Polysilicon Layer on Wafer Surface

Out of the polysilicon layers formed on either side surface of the silicon wafer, the polysilicon layer on the front side of the wafer is removed. This is performed to form extrinsic gettering sites on the back side of the wafer while securing the front side of the wafer as an active region for forming a device. Even if contamination by metal impurities is caused in the active region of the wafer before the BMD as functioning to be gettering sites is formed inside the wafer by the oxygen precipitation heat treatment to be performed later or the heat treatment to be performed in the device fabrication process, the contaminant impurities can be removed from the active region by the extrinsic gettering applied to the back side of the wafer.

The polysilicon layer can be removed by mechanical polishing, but not limited thereto. Any method capable of removing the polysilicon layer without affecting the flatness of the silicon wafer surface can be applied. For example, chemical-mechanical polishing (CMP) which is well known as a surface treatment technique for silicon wafer, machining treatment such as grinding, chemical processing treatment such as acid etching, etc. can be applied.

Since a damage (distortion) is incurred to the vicinity of the wafer surface abutting the polysilicon layer by the polysilicon layer formation, the thickness to be removed is desirably set to several times the thickness of the formed polysilicon layer or more. For example, when a polysilicon layer of 1.5 μm in thickness is formed, as shown in after-mentioned EXAMPLES, it is desirable to remove a portion of about 10 μm in thickness from the surface.

The second production method of the present invention includes the steps of: subjecting a silicon wafer, which has been sliced from a silicon single crystal ingot grown by the CZ method, to RTA treatment in a nitriding gas atmosphere; forming an oxide film on the back side of the wafer after the RTA treatment; and forming a polysilicon layer on the back side of the wafer on which the oxide film was formed.

The RTA treatment in a nitriding gas atmosphere is the same as the RTA treatment in the first production method. The subsequent oxide film formation and polysilicon layer formation are performed similarly to those in the first production method, except that the formations are performed not on a surface of either side of the silicon wafer, but on the back side thereof. only. Since the polysilicon layer is from the first formed on the back side of the silicon wafer while leaving the front side of the wafer intact, there is no need to apply the step of removing the polysilicon layer on the front side of the wafer, which is performed in the first production method.

The polysilicon layer formation on the back side of the silicon wafer can be carried out by a method such that only the back side of the wafer is exposed while covering the front side of the wafer by use of a specific tool or coating material.

By the second production method of the present invention, also, the extrinsic gettering sites can be formed on the back side of the wafer while securing the front side of the wafer as an active region for device formation.

In the method of the present invention for producing a silicon wafer, if a wafer composed of a defect-free region could be used as the silicon wafer to be subjected to the RTA treatment, a defect-free layer can be stably secured on the wafer surface part.

The “wafer composed of a defect-free region” referred to herein means a silicon wafer composed of a perfect region that is free of what are introduced during single crystal growth, such as aggregates of interstitial silicon type point defects (called “dislocation cluster”), aggregates of vacancy-type point defects (called “COP”) and OSF (Oxidation Induced Stacking Fault) nucleus-forming region.

The silicon single crystal ingot to be used for the production of the above-mentioned wafer composed of a defect-free region can be obtained by maintaining V/G within an appropriate range to be described later, given that the pulling rate of single crystal is V, and the temperature gradient along a growth direction within the single crystal just after it is pulled up is G.

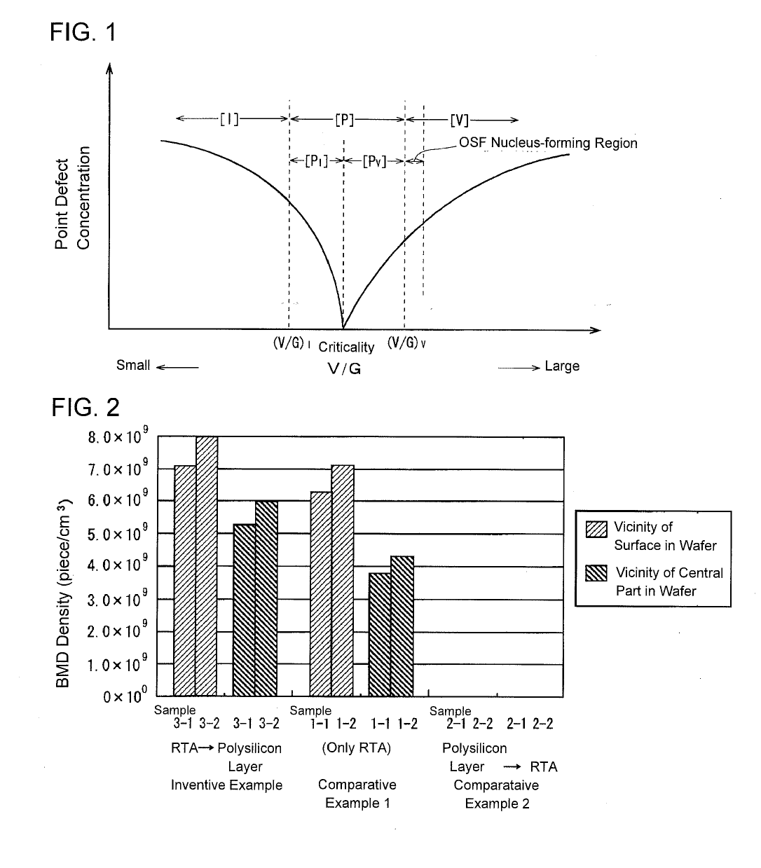

FIG. 1 is a view shown in the above-mentioned Patent Literature 1, which graphically expresses a relationship of V/G with concentrations of interstitial silicon-type point defects and vacancy-type point defects. This view illustrates that the boundary between a vacancy region and an interstitial silicon region is determined by V/G, which is called “Voronkov's theory”.

In FIG. 1, a region with V/G of horizontal axis being smaller than a critical point is the region where interstitial silicon-type point defects are predominantly present, and Region [I] with V/G being smaller than (V/G)_{I} is the region where aggregates of interstitial silicon-type point defects (dislocation cluster) are present. On the other hand, a region with V/G being larger than the critical point is the region where vacancy-type point defects are predominantly present, and Region [V] with V/G being larger than (V/G)_{V} is the region where aggregates of vacancy-type point defects (COP) are present. Region [P] between (V/G)_{I} and (V/G)_{V} is a perfect region free of either aggregates of interstitial silicon-type point defects or aggregates of vacancy-type point defects. Within the Region [P], with reference to the critical point as a boundary, a territory where the interstitial silicon-type point defects are predominant is Region [P_{I}], whereas a territory where the vacancy-type point detects are predominant is region [P_{V}]. In Region [V] adjacent to Region [P], an OSF nucleus-forming region where OSF (Oxidation Induced Stacking Fault) nuclei are formed is present.

As shown in FIG. 1, the pulling rate of single crystal is adjusted to maintain the V/G within the range of (V/G)I to (V/G)_{V}, whereby a silicon single crystal ingot entirely composed of the perfect region [P] is obtained, and a wafer entirely composed of the defect-free region can be sliced from this ingot.

Since this wafer is free of crystal defects such as COP, dislocation cluster and OSF nucleus-forming region, the defect-free layer can be stably secured in the wafer surface part without a risk such that these defects might be partially left without being removed thoroughly by the RTA treatment and the oxygen precipitation heat treatment or the like to be performed after the polysilicon layer formation. Further, since it hardly contains interstitial silicon-type point defects which extinguish the vacancies, injection of vacancies necessary for oxygen precipitation can be efficiently performed by the RTA treatment.

In a silicon wafer thus obtained by the method of the present invention for producing a silicon wafer, BMD is increased in the vicinity of a depth-wise central part of wafer (within the range of 350 to 450 μm from the wafer surface) and in the vicinity of surface thereof (within the range of 50 to 150 μm from the wafer surface) as described above, and the defect-free layer is formed in the surface part of the wafer on which a semiconductor device is to be formed. During which this wafer is transferred to the device fabrication process as the material of a semiconductor device substrate or the like, and subjected to heat treatment associated with the same process, the oxygen precipitation successively proceeds inside the wafer to enhance the BMD density, thereby incorporating intrinsic gettering in addition to the extrinsic gettering by the polysilicon layer.

In the method of the present invention for producing a silicon wafer, an embodiment such that, after a series of treatments as afore-mentioned (RTA treatment, oxide film formation, polysilicon layer formation, and removal of a polysilicon layer on the front side of the wafer), the wafer is further heat-treated at a temperature lower than that of the above-mentioned RTA treatment (such heat treatment is referred also to as “oxygen precipitation heat treatment” since BMD is precipitated inside the wafer) to thereby precipitate BMD in the internal vacancies of the wafer while forming the defect-free layer on the wafer surface is desirably adopted.

This oxygen precipitation heat treatment can be carried out according to a commonly-used method. For example, the heat treatment is performed under a condition adopted in after-mentioned EXAMPLES, that is, heat treatment is performed at 1000° C. for 16 hours within a heat treatment furnace under atmospheric pressure, whereby oxygen precipitation is promoted to form high-density BMD inside the wafer. In the wafer surface part, COP or the like is removed by the injected interstitial silicon while dispersing the vacancies outwardly, whereby the defect-free layer is formed.

By this oxygen precipitation heat treatment, the oxygen precipitation is promoted inside the wafer to enhance the BMD density, and the wafer is incorporated with the intrinsic gettering with high gettering performance in addition to the extrinsic gettering by polysilicon layer. On the other hand, the defect-free layer is formed in the wafer surface part. Therefore, independently from the heat treatment in the device fabrication process, a silicon wafer incorporated with the intrinsic gettering with high performance in addition to the extrinsic gettering and having the defect-free layer formed in the wafer surface part is obtained.

According to the above-mentioned method of the present invention for producing a silicon wafer, a silicon wafer improved in overall gettering performance, which has the defect-free layer formed in the wafer surface part and is incorporated with the extrinsic gettering by the polysilicon layer formation on the back side of the wafer and the intrinsic gettering by the precipitation of BMD inside the wafer can be produced.

A silicon wafer of the present invention is the silicon wafer having high gettering performance, which is produced by the method of the present invention for producing a silicon wafer.

The silicon wafer of the present invention, as described above, has the polysilicon layer which functions as extrinsic gettering sites on the back side of the wafer, and includes BMD acting as intrinsic gettering sites, which is formed in the vicinity of a depth-wise central part of the wafer (in the range of 350 to 450 μm from the wafer surface) and in the vicinity of surface thereof (in the range of 50 to 150 μm from the wafer surface) during the process of forming the polysilicon layer. The silicon wafer further includes the defect-free layer formed in the surface part. In this wafer, the oxygen precipitation successively proceeds inside the wafer while it is heat-treated in the device fabrication process as the device fabrication material, whereby the BMD density is enhanced.

In this way, a silicon wafer of the present invention is the silicon wafer incorporated with extrinsic gettering and intrinsic gettering, and thus enhanced in overall gettering performance. Although the intrinsic gettering sites are not necessarily sufficient until BMD is sufficiently precipitated by heat treatment of the wafer in the device fabrication process or the oxygen precipitation heat treatment, the extrinsic gettering sites by the polysilicon layer formation functions as the gettering sites until the BMD is sufficiently formed inside the wafer by the heat treatment in the device fabrication process or the oxygen precipitation heat treatment.

When a silicon wafer of the present invention is the wafer composed of a defect-free region, this silicon wafer is free from a risk such that crystal defects such as COP, OSF nucleus-forming region and dislocation cluster might be partially left since it does not contain such defects from the material stage. Since the vacancies necessary for oxygen precipitation can be efficiently injected by the RTA treatment as described above, high-density BMD can be precipitated inside the wafer. Accordingly, this silicon wafer can be used for device fabrication as the wafer having high intrinsic gettering performance in addition to extrinsic gettering performance.

When a silicon wafer of the present invention is the wafer subjected to the oxygen precipitation heat treatment, this silicon wafer is the wafer having excellent overall gettering performance, which is enhanced in BMD density and thus incorporated with the intrinsic gettering with high gettering performance in addition to the extrinsic gettering by the polysilicon layer.

### EXAMPLES

Using two kinds of silicon wafers where an oxygen concentration is 11×10¹⁷ atoms/cm³ and 15×10¹⁷ atoms/cm³ (ASTM F-121, 1979) respectively, each being composed of a defect-free region of 200 mm in diameter, RTA treatment was performed in nitriding gas atmosphere (Ar gas containing 0.5% NH₃O) by use of an RTA treatment furnace. Successively, an oxide film was formed on a surface of either side of each wafer, a polysilicon layer of 1.5 μm thick was formed further thereon, and the polysilicon layer on the front side of the wafer was removed (removal thickness is 15 μm). The resulting wafer was subjected to precipitation heat treatment for forming BMD, and a cross-sectional surface of the wafer was selectively etched to measure the BMD density. For comparison, the same measurement was performed either in the case where only the RTA treatment was performed (Comparative Example 1) or in the case where the order of processing was changed and the RTA treatment was performed after the polysilicon layer formation (Comparative Example 2). The silicon wafer with oxygen concentration of 11×10¹⁷ atoms/cm³ corresponds to Sample 3-1, Sample 1-1 and Sample 2-1 in Inventive Example, Comparative Example 1 and Comparative Example 2, respectively. The silicon wafer with oxygen concentration of 15×10¹⁷ atoms/cm³ corresponds to Sample 3-2, Sample 1-2 and Sample 2-2 in Inventive Example, Comparative Example 1, and Comparative Example 2, respectively.

A lamp anneal furnace was used for the RTA treatment. Table 1 shows the heat-up condition, the treatment temperature and time in film formation, the cool-down condition, and the like.

TABLE 1

| Step | | Operation Conditions of RTA Treatment |
|---|---|---|
| 1. | Furnace Gas | The internal atmosphere of the furnace is |
| | Substitution Step | substituted by a large quantity of Ar gas. |
| 2. | Heat-up Step 1 | Temperature is raised to 800° C. in Ar gas. |
| 3. | Heat-up Step 2 | Temperature is raised to 1150° C. by |
| | | supplying Ar gas and NH₃ gas into the furnace. |
| | | Heat-up rate: 50° C./s |
| 4. | Isothermal | The furnace is held at 1150° C. for 60 seconds by |
| | Treatment Step | supplying Ar gas and HN₃ gas into the furnace. |
| 5. | Cool-down Step | Temperature is lowered from 1150° C. to 800° C. |
| | | by supplying Ar gas and HN₃ gas to the furnace. |
| | | Cool-down rate: 70° C./s |
| 6. | Furnace Gas | The internal atmosphere of the furnace is |
| | Substitution Step | substituted by a large quantity of Ar gas. |
| | | Thereafter, the temperature is further lowered to |
| | | complete the treatment. |

The oxide film formation (oxide film deposition) was performed by heating the silicon wafer at 665° C. for 10 minutes in oxygen-containing atmosphere (air), after etching both surfaces of wafer subjected to the RTA treatment with 6% hydrofluoric acid solution.

In the polysilicon layer formation, polysilicon layers were formed on both surfaces of the silicon wafer by the CVD method using silane as a source material. Table 2 shows operation conditions in the oxide film deposition and in the polysilicon layer formation.

TABLE 2

| Step | | Operation Conditions |
|---|---|---|
| 1. | Oxide Film | Temperature: 665° C. |
| | Deposition | Atmosphere: Oxygen-containing atmosphere (air) |
| | | Time: 10 minutes |
| 2. | Polysilicon Layer | Temperature: 665° C. |
| | Formation | Atmosphere: Silane (source material) |
| | | Pressure: 3.99 × 10³ Pa (30 Torr) |
| | | Film Thickness: 1.5 μm |

For measuring the BMD density inside the wafer, a treatment of heating at 1000° C. for 16 hours under atmospheric pressure was performed as a precipitation heat treatment for forming BMD. By this precipitation treatment, minute oxygen precipitate nuclei, if present inside the wafer, can be grown to a size detectable as BMD.

The measurement of BMD density was performed by developing cleavage fracture in the silicon wafer, selectively etching a cross-section of such cleavage fracture of the wafer with Secco solution to a depth of 2 μm, then microscopically observing two portions of the wafer, one being in the vicinity of surface (the portion in the range of 50 to 150 μm in the depth direction from the wafer surface) and the other being in the vicinity of a depth-wise central part (the portion in the range of 350 to 450 μm in a depth direction from the wafer surface), and calculating BMD density based on the observation results.

Table 3 shows the measurement result of BMD density. The measurement result is graphically shown also in FIG. 2, in which the BMD density in a silicon wafer produced by the production method of the present invention is compared with the comparative examples.

TABLE 3

| | | | BMD Density | |
|---|---|---|---|---|
| | | | (piece/cm³) | |
| | | | | Vicinity of |
| | | | Vicinity of | Central |
| | | | Surface in | Part in |
| | | | Wafer | Wafer |
| Inventive | RTA treatment | Sample 3-1 | 7.1 × 10⁹ | 5.3 × 10⁹ |
| Example | → Polysilicon | Sample 3-2 | 8.0 × 10⁹ | 6.0 × 10⁹ |
| | layer formation | | | |
| Comparative | Only RTA | Sample 1-1 | 6.3 × 10⁹ | 3.8 × 10⁹ |
| Example 1 | treatment | Sample 1-2 | 7.1 × 10⁹ | 4.3 × 10⁹ |
| Comparative | Polysilicon | Sample 2-1 | <1.0 × 10⁰ | <1.0 × 10⁰ |
| Example 2 | layer formation | Sample 2-2 | <1.0 × 10⁰ | <1.0 × 10⁰ |
| | → RTA | | | |
| | treatment | | | |

As shown in Table 3 and FIG. 2, in comparison under the same oxygen concentration, the BMD density was high both in the vicinity of surface of wafer and in the vicinity of a depth-wise central part of wafer in Inventive Example (Samples 3-1 and 3-2: where RTA treatment→Polysilicon layer formation), compared with Comparative Example 1 (Samples 1-1 and 1-2: Only RTA treatment). This seems to be attributable to that precipitate nuclei of BMD are grown in the process of the polysilicon layer formation. The reason that the BMD density of the sample with oxygen concentration of 15×10¹⁷ atoms/cm³ was higher than that of the sample with oxygen concentration of 11×10¹⁷ atoms/cm³ is considered to be that the higher the oxygen concentration is, the larger the number of BMD precipitate nuclei inside the wafer is. In Comparative Example 2 (Samples 2-1 and 2-2: where Polysilicon layer formation→RTA treatment), BMD did not generate at either the oxygen concentrations of 11×10¹⁷ atoms/cm³ or 15×10¹⁷ atoms/cm³, since the injection of vacancies into the silicon wafer is blocked by the polysilicon layers in the process of the RTA treatment, and the oxygen precipitate nuclei generated inside the wafer in the process of forming the polysilicon layers on both surfaces of the wafer were extinguished by the RTA treatment.

From the above-mentioned examinations, it could be confirmed that, by applying the method of the present invention for producing a silicon wafer, a silicon wafer having a defect-free layer in the wafer surface part and improved in intrinsic gettering performance can be obtained. It was also confirmed that since the polysilicon layer formation is performed after forming the oxide film(s) on both surfaces or on the back side of the silicon wafer after the RTA treatment in the present invention, the polysilicon layer(s) can be formed, without forming a single crystal silicon layer and without hindrance, on both the surfaces or on the back side of the wafer, and the gettering performance is thus further enhanced by not only the intrinsic gettering but also the extrinsic gettering effect by the polysilicon layer.

### INDUSTRIAL APPLICABILITY

According to the method of the present invention for producing a silicon wafer, a silicon wafer further enhanced in gettering performance, which has a defect-free region in the surface part and is incorporated with extrinsic gettering and intrinsic gettering, can be produced. The extrinsic gettering is incorporated by the formation of the polysilicon layer on the back side of the wafer. The intrinsic gettering is incorporated by the polysilicon layer forming step and further the subsequent oxygen precipitation heat treatment or heat treatment in a device fabrication process to which the wafer is used as a source material. A silicon wafer of the present invention is the silicon wafer which is produced by the production method of the present invention and improved in overall gettering performance, and this wafer can be suitably used for a semiconductor device substrate or the like.

Consequently, the present invention can be extensively used in production of silicon wafers and semiconductor devices.

1. A method of producing a silicon wafer, comprising the steps of:
subjecting a silicon wafer, which has been sliced from a silicon single crystal ingot grown by the Czochralski method, to RTA treatment in a nitriding gas atmosphere;
forming an oxide film on a surface of either side of the wafer after the RTA treatment;
forming a polysilicon layer on a surface of either side of the wafer, the surface having an oxide film formed thereon; and
removing the polysilicon layer on the front side of the wafer among them thus formed.

2. A method of producing a silicon wafer, comprising the steps of:
subjecting a silicon wafer, which has been sliced from a silicon single crystal ingot grown by the Czochralski method, to RTA treatment in a nitriding gas atmosphere;
forming an oxide film on the back side of the wafer after the RTA treatment; and
forming a polysilicon layer on the back side of the wafer with the oxide film formed thereon.

3. The method of producing a silicon wafer according to claim 1, wherein a silicon wafer to be subjected to the RTA treatment is composed of a defect-free region.

4. The method of producing a silicon wafer according to claim 1, wherein the step of forming an oxide film includes an operation in which the wafer is heated in an oxidizing atmosphere, after treating the wafer surface with hydrofluoric acid.

5. The method of producing a silicon wafer according to claim 1, wherein the step of forming an oxide film includes an operation in which the wafer is heated in an oxidizing atmosphere, after polishing the wafer surface.

6. A method of producing a silicon wafer, wherein a silicon wafer produced by the production method according to claim 1 is heat treated at a temperature lower than that of the RTA treatment to precipitate oxygen at vacancies inside the wafer while forming a defect-free layer on the wafer surface.

7. A silicon wafer having high gettering performance, being produced by the production method according to claim 1.

8. A silicon wafer having high gettering performance, comprising precipitate nuclei inside the wafer, the nuclei functioning to form an oxygen precipitate layer by heat treatment to be performed in a semiconductor device fabrication process; and a polysilicon layer on the back side of the wafer.

9. A silicon wafer having high gettering performance, comprising: an oxygen precipitate layer inside the wafer; and a polysilicon layer on the back side of the wafer.
